(19) United States
(12) Patent Application Publication
(10) Pub. No.: US 2012/0252224 A1
(43) Pub. Date: Oct. 4, 2012

(54) METHOD OF DEPOSITING SILICON OXIDE FILM AND SILICON NITRIDE FILM, FILM FORMING APPARATUS, AND METHOD OF MANUFACTURING SEMICONDUCTOR DEVICE

(75) Inventors: Atsushi ENDO, Nirasaki City (JP); Masaki KUROKAWA, Nirasaki City (JP); Hiroki IRIUDA, Nirasaki City (JP)

(73) Assignee: TOKYO ELECTRON LIMITED, Tokyo (JP)

(21) Appl. No.: 13/432,611

(22) Filed: Mar. 28, 2012

(30) Foreign Application Priority Data
Mar. 30, 2011 (JP) 2011-076461

(51) Int. Cl. H01L 21/316; B05C 11/10; H01L 21/318

(52) U.S. Cl. 438/763; 118/695; 257/E21.279; 257/E21.293

(57) ABSTRACT

A method of depositing a silicon oxide film and a silicon nitride film includes depositing the silicon oxide film and the silicon nitride film on a substrate, and a gas for forming the silicon nitride film further includes boron.

### CROSS-REFERENCE TO RELATED PATENT APPLICATIONS

This application claims the benefit of Japanese Patent Application No. 2011-076461, filed on Mar. 30, 2011 in the Japan Patent Office, the disclosure of which is incorporated herein in its entirety by reference.

### BACKGROUND OF THE INVENTION

1. Field of the Invention

The present invention relates to a method of depositing a silicon oxide film and a silicon nitride film, a film forming apparatus, and a method of manufacturing a semiconductor device.

2. Description of the Related Art

A semiconductor integrated circuit apparatus includes a deposited structure in which, for example, a silicon film and a silicon oxide film, or a non-doped silicon film and a doped silicon film, are deposited.

Recently, accompanying high integration progression, there has been so-called three-dimensionalization of a device, that is, a device such as a transistor or a memory cell is deposited upward from a surface of a semiconductor wafer in a semiconductor integrated circuit apparatus. When the so-called three-dimensionalization process is performed, the number of deposited layers in the deposited structure is enormous compared with a current semiconductor integrated circuit apparatus mainly including a planar-type device. For example, Patent Reference 1 discloses a semiconductor device including a three-dimensionalized memory cell formed by depositing a plurality of silicon films and silicon oxide films, or a plurality of non-doped silicon films and doped silicon films.

The deposited structure may include a combination of a silicon oxide film and a silicon nitride film, besides the silicon film and the silicon oxide film, or the non-doped silicon film and the doped silicon film.

However, in the deposited structure of the silicon oxide film and the silicon nitride film, when the number of deposited films increases, bending of a semiconductor wafer at room temperature gradually increases, and finally the semiconductor wafer is broken. The above phenomenon becomes severe when the silicon nitride film is formed by using, specifically, a dichlorosilane (DCS) gas and an ammonia (NH₃) gas.

3. Prior Art Reference
(Patent Reference 1) Japanese Patent Laid-open Publication No. 2010-225694

### SUMMARY OF THE INVENTION

The present invention provides a method of depositing a silicon oxide film and a silicon nitride film, which is capable of preventing bending of a substrate on which a deposited structure is formed from increasing even when the number of deposited silicon oxide films and silicon nitride films increases, and a film forming apparatus capable of executing the depositing method, and a method of manufacturing a semiconductor device by using the depositing method.

According to an aspect of the present invention, there is provided a method of depositing a silicon oxide film and a silicon nitride film on a substrate, wherein boron is added in a gas for forming the silicon nitride film.

According to another aspect of the present invention, there is provided a method of depositing a silicon oxide film and a silicon nitride film on a substrate, the method including: (1) accommodating a plurality of substrates, on each of which a deposited film of the silicon oxide film and the silicon nitride film is to be formed, in a processing chamber wherein a side portion of each of the substrates is held; (2) supplying a silicon oxide material gas and an oxidizing agent into the processing chamber, when the silicon oxide film is formed; (3) supplying a silicon material gas, a nitrating agent, and a boron-containing gas into the processing chamber, when the silicon nitride film is formed; and (4) forming the deposited films of the silicon oxide films and the silicon nitride films on a surface and a rear surface of each of the plurality of substrates by repeating processes (2) and (3).

According to another aspect of the present invention, there is provided a film forming apparatus forming a deposited film of a silicon oxide film and a silicon nitride film on a substrate, the film forming apparatus including: a processing chamber which accommodates a plurality of substrates, on which the deposited film of the silicon oxide film and the silicon nitride film is to be formed, wherein a side portion of each of the substrates is held; a gas supply mechanism which supplies a gas used in a process into the processing chamber; an exhauster which evacuates an inside of the processing chamber; and a controller which controls the gas supply mechanism and the exhauster, wherein the controller controls the gas supply mechanism and the exhauster to execute processes (2) through (4) in the above method of depositing a silicon oxide film and a silicon nitride film.

According to another aspect of the present invention, there is provided a method of manufacturing a semiconductor device including a deposited film, in which a silicon oxide film and a silicon nitride film are repeatedly deposited, the method including: (1) accommodating a plurality of substrates, on each of which the deposited film of the silicon oxide film and the silicon nitride film is to be formed, in a processing chamber wherein a side portion of each of the substrates is held; (2) supplying a silicon oxide material gas and an oxidizing agent into the processing chamber, when the silicon oxide film is formed; (3) supplying a silicon material gas, a nitrating agent, and a boron-containing gas into the processing chamber, when the silicon nitride film is formed; (4) forming the deposited films of the silicon oxide films and the silicon nitride films on a surface and a rear surface of each of the plurality of substrates by repeating processes (2) and (3); and (5) removing the deposited film formed on the rear surface of each of the plurality of substrates, after finishing the forming of the deposited film.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram showing a relation between a boron concentration in a SiBN film and a stress applied to a silicon wafer from the SiBN film;

FIG. 2 is a diagram showing a relation between a boron concentration in a SiBN film and an atomic composition ratio of the SiBN film;

FIG. 3 is a diagram showing a relation between a boron concentration in a SiBN film and haze of the SiBN film;

FIG. 4 is a schematic cross-sectional view of a film forming apparatus capable of executing a method of depositing a silicon oxide film and a silicon nitride film, according to an embodiment of the present invention;

FIGS. 5A through 5E are cross-sectional views for describing an example of a method of manufacturing a semiconductor device by using the method of depositing the silicon oxide film and the silicon nitride film, according to an embodiment of the present invention;

FIGS. 6A through 6C are schematic cross-sectional views of a silicon wafer on which a deposited structure is formed.

### DETAILED DESCRIPTION OF THE INVENTION

### Mode for Carrying Out the Invention

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

Hereinafter, embodiments of the present invention will be described with reference to accompanying drawings. In drawings, like reference numerals denote like elements.

(Method of Depositing a Silicon Oxide Film and a Silicon Nitride Film)

It seems that a substrate on which a plurality of silicon oxide films and a plurality of silicon nitride films are deposited is broken when a film forming temperature returns to room temperature, because the silicon nitride films in particular apply stress to the substrate, for example, a silicon wafer. Thus, inventors of the present invention have tried to reduce the stress applied to the substrate from the silicon nitride films.

In this environment, the present inventors found that the stress applied to the substrate, for example, the silicon wafer, from the silicon nitride films may be reduced by adding boron in a film forming gas, when the silicon nitride films are formed.

The silicon nitride film formed by adding the boron in the film forming gas is a SiBN film, in which boron B is contained in silicon nitride (SiN). However, the SiBN film has no functional difference from the silicon nitride (SiN) film. Thus, the SiBN film may substitute for the SiN film in a deposited film of the silicon oxide film and the silicon nitride film, for example, a SiO₂ film and the SiN film.

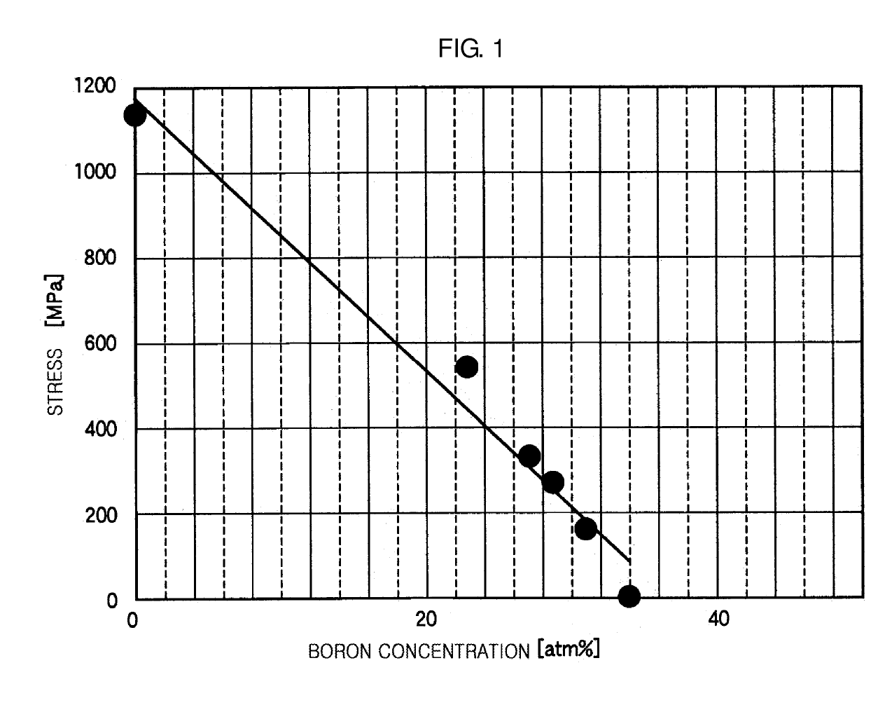

FIG. 1 is a diagram showing a relation between boron concentration in the SiBN film and the stress applied to the silicon wafer from the SiBN film.

As shown in FIG. 1, when the boron concentration is 0 atm %, that is, in the silicon nitride (SiN) film, stress applied to the silicon wafer is about 1142 MPa.

On the other hand, when the SiBN film in which boron concentration is about 23 atm % is used, the stress applied to the silicon wafer is about 545 MPa, and it is apparent that the stress is reduced.

In addition, as the boron concentration is gradually increased, the stress is reduced to about 338 MPa when the SiBN film has the boron concentration of about 27 atm %, about 271 MPa when the SiBN film has the boron concentration of about 29 atm %, about 168 MPa when the SiBN film has the boron concentration of about 31 atm %, and about 8 MPa when the SiBN film has the boron concentration of about 34 atm %.

Examples of gases for forming the SiBN film are as follows.

Silicon material gas: dichlorosilane (SiH₂Cl₂: DCS)

Nitrating agent: ammonia (NH₃)

Boron containing gas: boron trichloride (BCl₃)

Examples of conditions when a SiBN film having a film thickness of about 50 nm is formed in a chemical vapor deposition (CVD) method by using a batch-type vertical film forming apparatus are as follows.

DCS flow rate: NH₃ flow rate=1:1 to 1:20

BCl₃ flow rate=10 sccm to 150 sccm

Film forming temperature=600° C. to 800° C.

In addition, in order to change the boron concentration, the BCl₃ flow rate may be changed in a state where the ratio between the DCS flow rate and the NH₃ flow rate (DCS flow rate: NH₃ flow rate) and the processing temperature are constantly maintained.

As described above, when the silicon nitride film is formed, the silicon nitride film containing the boron, for example, the SiBN film, is formed by adding the boron in the film forming gas, and thus the SiBN film applying less stress to the silicon wafer than that of the silicon nitride films may be obtained.

The SiBN film may substitute for the SiN film, in a deposited structure in which a plurality of silicon oxide films and a plurality of silicon nitride films, for example, SiO₂ films and SiN films, are deposited in a semiconductor integrated circuit apparatus. By replacing the SiN film with the SiBN film, even when the number of deposited silicon oxide films and the silicon nitride films is increased, a method of depositing the silicon oxide films and the silicon nitride films capable of preventing the bending of the substrate, on which the deposited structure in which the above films are deposited is formed, from increasing may be obtained.

In addition, the present inventors examined an atomic composition of the SiBN film at each of the boron concentration levels.

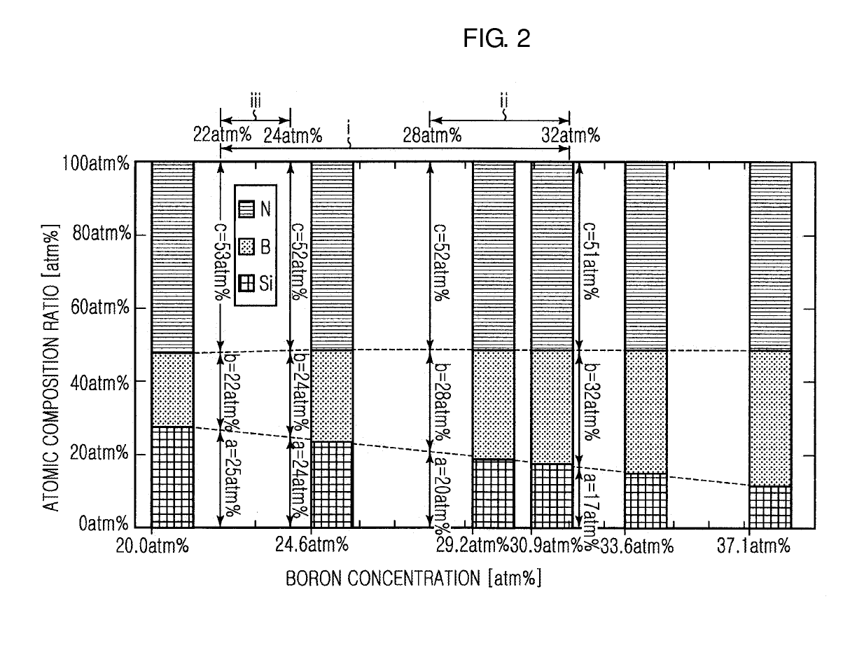

FIG. 2 is a diagram showing a relation between the boron concentration in the SiBN film and an atomic composition ratio of the SiBN film.

As shown in FIG. 2, when the boron concentration increases, the atomic composition ratio (atomic composition percentage) of a nitrogen (N) atom in the SiBN film rarely changes or slightly reduces, and the atomic composition ratio of a silicon (Si) atom is definitely reduced.

For example, when the atomic composition ratio of the boron atom is about 22 atm %, the atomic composition ratio of the nitrogen atom is about 53 atm % and the atomic composition ratio of the silicon atom is about 25 atm %. A compositional formula in this case is Si₂₅B₂₂N₅₃.

When the atomic composition ratio of the boron atom increases to about 32 atm %, the atomic composition ratio of the nitrogen atom is about 51 atm % and the atomic composition ratio of the silicon atom is about 17 atm %. A compositional formula in this case is Si₁₇B₃₂N₅₁, and thus the number of the silicon atom decreases, the number of the boron atom increases, and the number of the nitrogen atom slightly decreases.

As described above, in the SiBN film, almost all silicon atoms are replaced by the boron atoms as the boron concentration increases.

Also, the present inventors examined flatness of the SiBN film at each of the boron concentration levels.

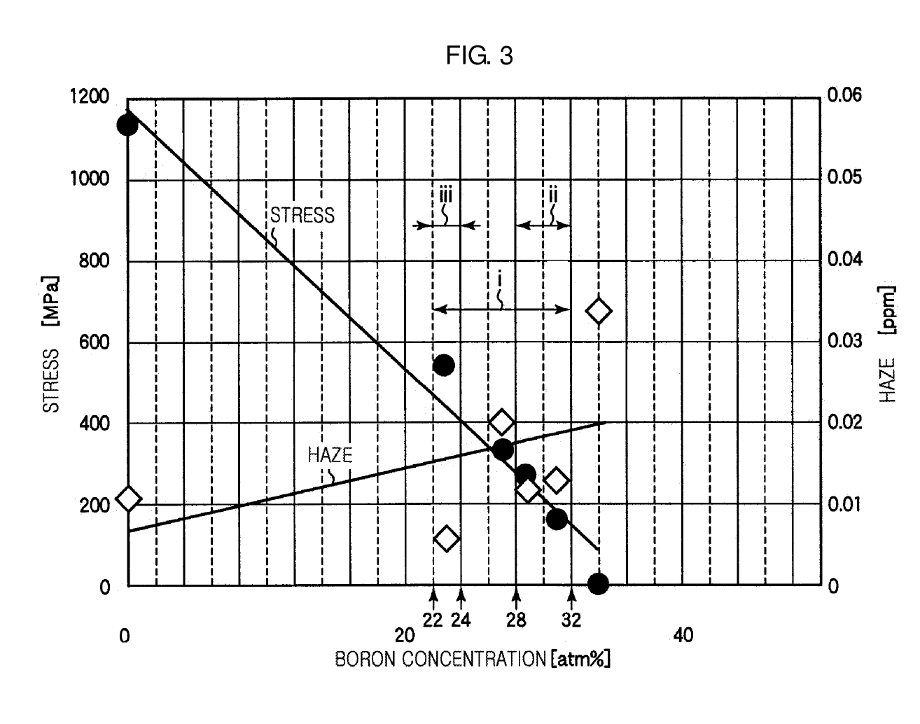

FIG. 3 is a graph showing a relation between the boron concentration in the SiBN film and haze of the SiBN film. In addition, FIG. 3 shows the relation between the boron concentration and stress shown in FIG. 1, where a left longitudinal axis denotes stress and a right longitudinal axis denotes haze. In FIG. 3, white lozenges denote plot points of the haze, and black circles denote plot points of the stress.

As shown in FIG. 3, when the boron concentration increases, a haze level also rises. That is, fine roughness on a surface of the SiBN film increases, and thus flatness of the SiBN film decreases. Thus, an upper limit of the boron concentration in the SiBN film may be defined based on the haze level. For example, it is preferable that the haze level is 0.02 ppm or less. Therefore, as shown in FIG. 3, the upper limit of the boron concentration in the SiBN film may be defined as about 32 atm %.

Also, regarding a lower limit of the boron concentration in the SiBN film, the lower limit of the boron concentration may be defined based on the stress level. For example, it is preferred that the stress level is reduced by half when comparing with that of the nitride silicon film (boron concentration=0 atm %). For example, when the boron concentration in the SiBN film is about 22 atm % or greater, the stress level is reduced by half. Thus, as shown in FIG. 3, the lower limit of the boron concentration in the SiBN film may be defined as about 22 atm %.

As described above, when the boron concentration in the SiBN film is controlled within a range from 22 atm % to 32 atm % (indicated by an arrow i), the SiBN film, the stress of which applied to the silicon wafer ranges from 100 MPa to 600 MPa that is about half the stress applied from the silicon nitride film and the haze level of which ranges from 0.005 ppm to 0.02 ppm, may be obtained.

When the SiBN film, in which the boron concentration is controlled as described above, is represented by using its atomic composition, the atomic composition ratio of SiₐB_{b}N_{c} can be a=25˜17 atm %, b=22˜32 atm %, and c=53˜51 atm %, as shown in FIG. 2.

In addition, when the boron concentration in the SiBN film is narrowed to a range from 28 atm % to 32 atm % (indicated by an arrow ii), the SiBN film which has less stress ranging from 100 MPa to 300 MPa may be obtained.

When the SiBN film, in which the boron concentration is controlled as described above, is represented by using its atomic composition, the atomic composition ratio of SiₐB_{b}N_{c} can be a=20˜17 atm %, b=28˜32 atm %, and c=52˜51 atm %, as shown in FIG. 2.

Also, the SiBN film of the above range may be an SiBN film in which the number of silicon atoms is less than the number of boron atoms. That is, according to the SiBN film in which the number of silicon atoms is less than that of the boron atoms, the stress is further reduced and a sufficient level of flatness may be obtained.

According to the SiBN film, in which the boron concentration ranges from 28 atm % to 32 atm %, the stress may be further reduced and the number of deposited silicon oxide films and the silicon nitride films may be further increased while restraining the bending of the substrate, for example, a silicon wafer, when comparing with, for example, the SiBN film in which the boron concentration is equal to 22 atm % or greater, and less than 28 atm %.

Meanwhile, the SiBN film, in which the boron concentration is equal to 22 atm % or greater, and less than 28 atm %, is advantageous in that the haze level is less than that of the SiBN film in which the boron concentration ranges from 28 atm % to 32 atm %, and thus the flatness is excellent. Thus, the SiBN film, in which the boron concentration is equal to 22 atm % or greater, and less than 28 atm %, may be adopted in a case where the number of deposited films is small or a flatness of high precision is required.

In addition, in FIG. 3, when the boron concentration is about 27 atm %, the haze level is 0.02 ppm, which deviates from a regression line. It seems that this is caused by unstable processes. When processes are strictly managed like actual processes of manufacturing a semiconductor integrated circuit apparatus, the haze level may be controlled around 0.01 ppm or less than 0.01 ppm based on plot points before and after.

Also, in consideration of the haze level only, when the boron concentration in the SiBN film is controlled within a range from 22 atm % to 24 atm % (denoted by an arrow iii), the haze level may range from about 0.005 ppm to about 0.01 ppm, that is superior to the haze level of the silicon nitride film, that is, about 0.011 ppm. Also, the stress is half the stress of the silicon nitride film or less. If the flatness of high precision is required, the SiBN film, in which the boron concentration ranges from 22 atm % to 24 atm %, may be adopted.

When the SiBN film, in which the boron concentration is controlled as described above, is represented by using the atomic composition, as shown in FIG. 2, the atomic composition ratio of SiₐB_{b}N_{c} may be represented with a=25˜24 atm %, b=22˜24 atm %, and c=53˜52 atm %.

Also, the SIBN film of the above range may be referred to as a SiBN film in which the number of silicon atoms is equal to or greater than the number of boron atoms. That is, when the number of silicon atoms is greater than the number of boron atoms, the SiBN film having greater flatness and less stress than those of the silicon nitride film may be obtained.

(Method of Manufacturing a Semiconductor Device, and a Film Forming Apparatus)

Next, an example of a method of manufacturing a semiconductor device by using the method of depositing the silicon oxide film and the silicon nitride film according to the embodiment, and an example of a film forming apparatus will be described.

First, the film forming apparatus will be described as follows.

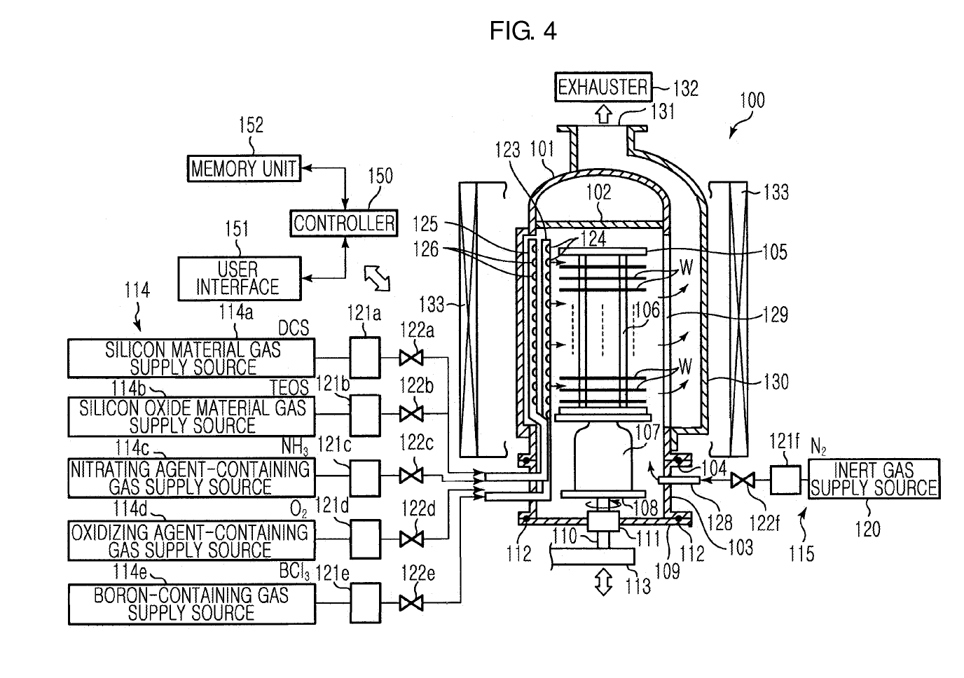

FIG. 4 is a schematic cross-sectional view of an example of the film forming apparatus capable of executing the method of depositing the silicon oxide film and the silicon nitride film according to an embodiment of the present invention.

As shown in FIG. 4, the film forming apparatus 100 includes a processing chamber 101 having a shape of a bottom-open cylinder with a ceiling. The entire processing chamber 101 is formed of, for example, quartz. A ceiling plate 102 formed of quartz is provided on the ceiling of the processing chamber 101. A manifold 103, which is molded of a stainless steel, for example, and has a cylindrical shape, is connected to a bottom opening of the processing chamber 101 via a sealing member 104, such as an O-ring.

The manifold 103 supports the bottom of the processing chamber 101. A wafer boat 105 formed of quartz, on which a plurality of, for example, 50 to 100, semiconductor wafers, in the present example, silicon wafers W, can be held as processing targets, may be inserted into the processing chamber 101 from a lower portion of the manifold 103. The wafer boat 105 includes a plurality of pillars 106, and the plurality of silicon wafers W are supported by recesses provided in the pillars 106.

The wafer boat 105 is placed on a table 108 via a thermos vessel 107 formed of quartz. The table 108 opens and closes the bottom opening of the manifold 103. For example, the table 108 is supported on a rotary shaft 110 that penetrates through a lid 109 formed of stainless steel. A magnetic fluid seal 111, for example, is provided on a penetration portion of the rotary shaft 110 in order to support the rotary shaft 110 to be rotatable while hermetically sealing the rotary shaft 110. A sealing member 112 formed of, for example, an O-ring, is interposed between a peripheral portion of the lid 109 and the bottom of the manifold 103. Accordingly, a sealing property in the processing chamber 101 may be maintained. The rotary shaft 110 is attached to a leading edge of an arm 113 supported by an elevation mechanism (not shown), for example, a boat elevator. Accordingly, the wafer boat 105, the lid 109, etc. are elevated together and are inserted to and pulled out from the processing chamber 101.

The film forming apparatus 100 includes a process gas supply mechanism 114 for supplying a gas used in a process into the processing chamber 101, and an inert gas supply mechanism 115 for supplying an inert gas into the processing chamber 101.

The process gas supply mechanism 114 includes a silicon material gas supply source 114a, a silicon oxide material gas supply source 114b, a nitrating agent-containing gas supply source 114c, and an oxidizing agent-containing gas supply source 114d in order to form silicon oxide films and silicon nitride films. In addition, the process gas supply mechanism 114 includes a boron-containing gas supply source 114e in order to add boron in a film forming gas for forming the silicon nitride films. An example of the silicon material gas may be dichlorosilane, an example of the silicon oxide material gas may be tetraethoxysilane (Si(C₂H₅O)₄:TEOS), an example of the nitrating agent-containing gas may be ammonia, an example of the oxidizing agent-containing gas may be oxygen (O₂), and an example of the boron-containing gas may be boron trichloride.

The inert gas supply mechanism 115 includes an inert gas supply source 120. The inert gas is used as a purge gas or the like. An example of the insert gas may be a nitrogen (N₂) gas.

The silicon material supply source 114a is connected to a distribution nozzle 123 via a flow rate controller 121a and an opening/closing valve 122a. The distribution nozzle 123 is a quartz pipe and penetrates a sidewall of the manifold 103 inwardly, is bent upward and vertically extends. A plurality of gas ejection holes 124 are provided in a vertical portion of the distribution nozzle 123 at predetermined intervals. The silicon material gas may be ejected evenly from each of the gas ejection holes 124 in a horizontal direction toward the inside of the processing chamber 101.

In addition, four distribution nozzles are prepared in the present embodiment. In FIG. 4, among the four distribution nozzles, only two distribution nozzles 123 and 125 are shown. The distribution nozzle 125 is also a quartz pipe and penetrates a sidewall of the manifold 103 inwardly, is bent upward and vertically extends. In addition, a plurality of gas ejection holes 126 are also provided in a vertical portion of the distribution nozzle 125 at predetermined intervals. Two remaining distribution nozzles that are not shown in FIG. 4 also have the same structure as the distribution nozzles 123 and 125.

The silicon oxide material gas supply source 114b is also connected to the distribution nozzle 123 via a flow rate controller 121b and an opening/closing valve 122b.

The nitrating agent-containing gas supply source 114c is connected to the distribution nozzle 125 via a flow rate controller 121c and an opening/closing valve 122c.

The oxidizing agent-containing gas supply source 114d is connected to another distribution nozzle that is not shown via a flow rate controller 121d and an opening/closing valve 122d.

The boron-containing gas supply source 114e is connected to still another distribution nozzle that is not shown via a flow rate controller 121e and an opening/closing valve 122e.

The inert gas supply source 120 is connected to a nozzle 128 via a flow rate controller 121f and an opening/closing valve 122f. The nozzle 128 penetrates through the side wall of the manifold 103 to eject the inert gas toward the inside of the processing chamber 101 horizontally from a leading edge thereof.

An exhaust port 129 for evacuating the inside of the processing chamber 101 is provided on a portion in the processing chamber 101, which is on an opposite side to the distribution nozzles 123 and 125. The exhaust port 129 is provided to be long and narrow by vertically cutting the sidewall of the processing chamber 101. An exhaust port cover member 130 having a U-shaped cross-section to cover the exhaust port 129 is weld-attached to a portion of the processing chamber 101 corresponding to the exhaust port 129. The exhaust port cover member 130 extends upward along a side wall of the processing chamber 101, thereby defining a gas outlet 131 on an upper portion of the processing chamber 101. An exhauster 132 including a vacuum pump or the like is connected to the gas outlet 131. The exhauster 132 evacuates the inside of the processing chamber 101 so as to exhaust the process gas used in the process and to adjust a pressure in the processing chamber 101 at a process pressure according to the process.

A heating device 133 having a cylindrical shape is provided on an outer circumference of the processing chamber 101. The heating device 133 activates the gas supplied into the processing chamber 101, and at the same time, heats a processing target, which, in the present embodiment, is the silicon wafer W, accommodated in the processing chamber 101.

Each element in the film forming apparatus 100 is controlled by a controller 150 including, for example, a micro-processor (computer). A user interface 151, such as a keyboard by which an operator performs command input and the like to manage the film forming apparatus 100, a display to visually display an operational status of the film forming apparatus 100, or the like, is connected to the controller 150.

A memory unit 152 is connected to the controller 150. The memory unit 152 stores a control program for executing various processes performed in the film forming apparatus 100 according to control of the controller 150, or a program, that is, a recipe, for instructing each component of the film forming apparatus 100 to execute a process according to process conditions. The recipe is stored in, for example, a recording medium in the memory unit 152. The recording medium may be a hard disk, a semiconductor memory, or a portable type medium such as a CD-ROM, a DVD, or a flash memory. Also, the recipe may be transmitted from another device through, for example, a dedicated line. If required, desired processes are performed by the film forming apparatus 100 under the control of the controller 150 by invoking a recipe from the memory unit 152 according to instructions or the like from the user interface 151 and performing a process based on the recipe in the controller 150.

Processes according to the method of manufacturing the semiconductor device by using the method of depositing the silicon oxide films and the silicon nitride films according to an embodiment of the present invention, which will be described below, are performed sequentially under the control of the controller 150.

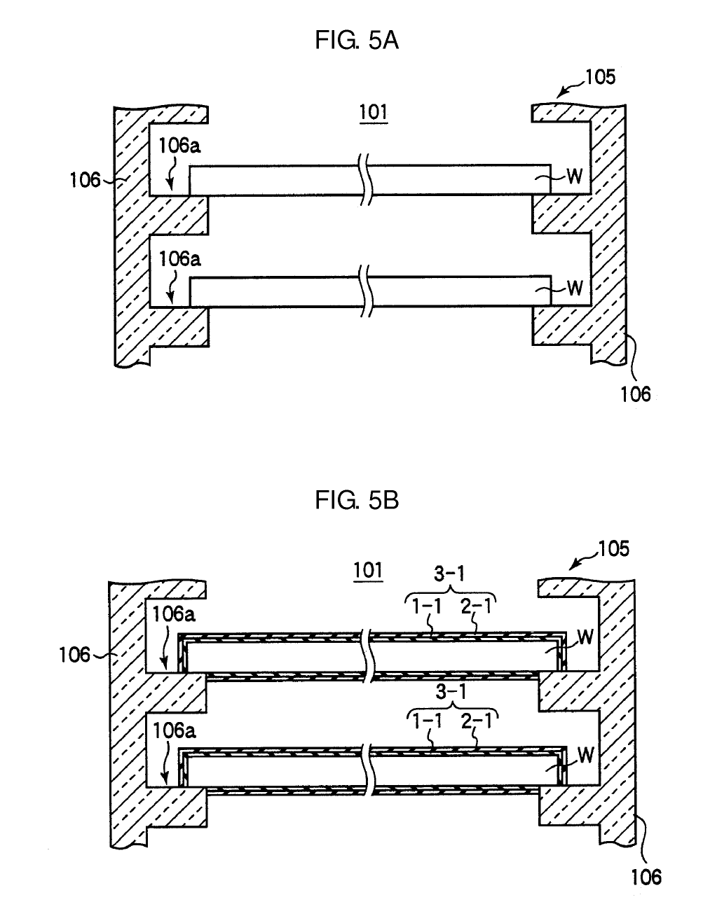

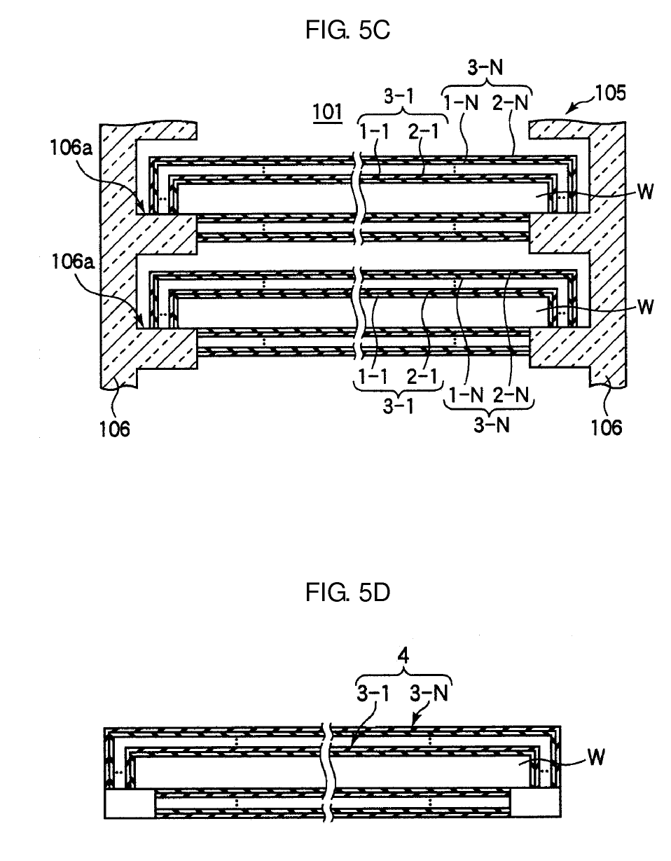

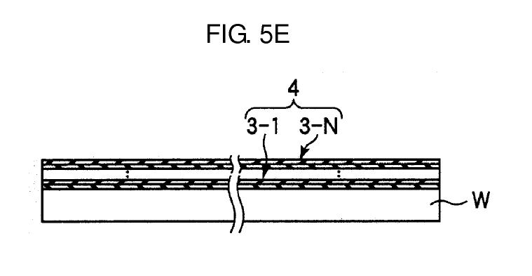

FIGS. 5A through 5E are cross-sectional views describing an example of the method of manufacturing the semiconductor device by using the method of depositing the silicon oxide films and the silicon nitride films according to an embodiment of the present invention.

First, as shown in FIG. 5A, a plurality of silicon wafers W are held on the wafer boat 105 in a multi stage manner. For example, the plurality of silicon wafers W are supported by the recesses 106a provided in each of the plurality of pillars 106 provided on the wafer boat 105. Next, the plurality of silicon wafers W held on the wafer boat 105 in the multi stage manner are inserted in the processing chamber 101.

Next, as shown in FIG. 5B, the silicon oxide material gas and the oxidizing agent-containing gas are supplied into the processing chamber 101 from the silicon oxide material gas supply source 114b and the oxidizing agent-containing gas supply source 114d, respectively, and then a first layer of silicon oxide film 1-1 is formed on surfaces, rear surfaces, and side surfaces of the plurality of silicon wafers W. An example of conditions for forming the silicon oxide film 1-1 is as follows.

Flow rate of TEOS=50 sccm to 500 sccm

Flow rate of O₂=10 sccm to 20 sccm

Film forming temperature=550° C. to 700° C.

In the above film forming conditions, a SiO₂ film having a film thickness of about 50 nm is formed as the silicon oxide film 1-1. In addition, an inert gas is supplied into the processing chamber 101 from the inert gas supply source 120 so as to purge the inside of the processing chamber 101.

Next, the silicon material gas, the nitrating agent-containing gas, and the boron-containing gas are supplied into the processing chamber 101 from the silicon material gas supply source 114a, the nitrating agent-containing gas supply source 114c, and the boron-containing gas supply source 114e, respectively, and then a first layer of a silicon nitride film 2-1 is formed on the silicon oxide film 1-1 that is formed on the surfaces, the rear surfaces, and the side surfaces of the plurality of silicon wafers W. As described above, an example of conditions for forming the silicon nitride film 2-1 is as follows.

DCS flow rate: NH₃ flow rate=1:1 to 1:20

BCl₃ flow rate=10 sccm to 150 sccm

Film forming temperature=600° C. to 800° C.

In the above film forming conditions, a SiBN film having a film thickness of about 50 nm is formed as the silicon nitride film 2-1. As such, a first deposited structure 3-1 including the silicon oxide film 1-1 and the silicon nitride film 2-1 is formed. In addition, the inert gas is supplied into the processing chamber 101 from the inert gas supply source 120 so as to purge the inside of the processing chamber 101.

After that, the forming of the deposited structures (3-1 to 3-N) including the silicon oxide film and the silicon nitride film is repeatedly performed to form a predetermined number (N) of deposited layers. Accordingly, as shown in FIG. 5C, N numbers of deposited structures (3-1 to 3-N) are formed on the surfaces, the rear surfaces, and the side surfaces of the silicon wafers W.

Then, the film forming process using the film forming apparatus 100 is finished.

In the film forming process using the film forming apparatus 100, the film forming temperature of the silicon oxide film and the film forming temperature of the silicon nitride film may be as close to each other as possible. That is, if the film forming temperatures of the silicon oxide film and the silicon nitride film are too different from each other, a time taken to change the film forming temperature, for example, changing of a set temperature of the heating device 133, and a time taken to stabilize the internal temperature of the processing chamber 101 increase, thereby greatly decreasing throughput. This decrease of throughput may be prevented when the difference between the film forming temperatures of the silicon oxide film and the silicon nitride film is generally within a range of about 50° C. to 150° C., although the temperature difference may vary according to a capacity of the processing chamber 101. Preferably, the film forming temperatures of the silicon oxide film and the silicon nitride film may be equal to each other. When the film forming temperature are equal to each other, there is no need to change the film forming temperature or stabilize the internal temperature of the processing chamber 101, and thus a maximum throughput from the film forming sequences may be obtained.

In the present embodiment, the film forming temperature of the SiO₂ film when using the TEOS and the film forming temperature of the SiBN film when using DCS—NH₃—BCl₃ are equal to each other, and thus, the SiO₂ film and the SiBN film are formed continuously and repeatedly. In addition, the number of deposited layers (N) is 20 to 40.

Also, since one layer of the SiO₂ film and the SiBN film is processed for 50 to 80 minutes, a batch type vertical film forming apparatus, in which 50 to 100 sheets of silicon wafer W are placed on the wafer boat 105 and processed integrally at once as described in the present embodiment, may be suitable for improving the throughput.

Next, as shown in FIG. 5D, the wafer boat 105 is carried out the processing chamber 101, and the silicon wafers W are carried out the wafer boat 105.

Then, as shown in FIG. 5E, a rear surface etching and a bevel etching are performed to each of the silicon wafers W, and a deposited structure body 4 including the first deposited structure 3-1 to the N-th deposited structure 3-N is removed from peripheries of the rear surface and the side surface of each of the silicon wafers W. The deposited structure body 4 is removed from the peripheries of the rear surface and the side surfaces of the silicon wafer W in order to maintain flatness on the rear surface of the silicon wafer W, and to perform manufacturing processes, for example, an exposure process, with high accuracy, even after the deposited structure body 4 is formed.

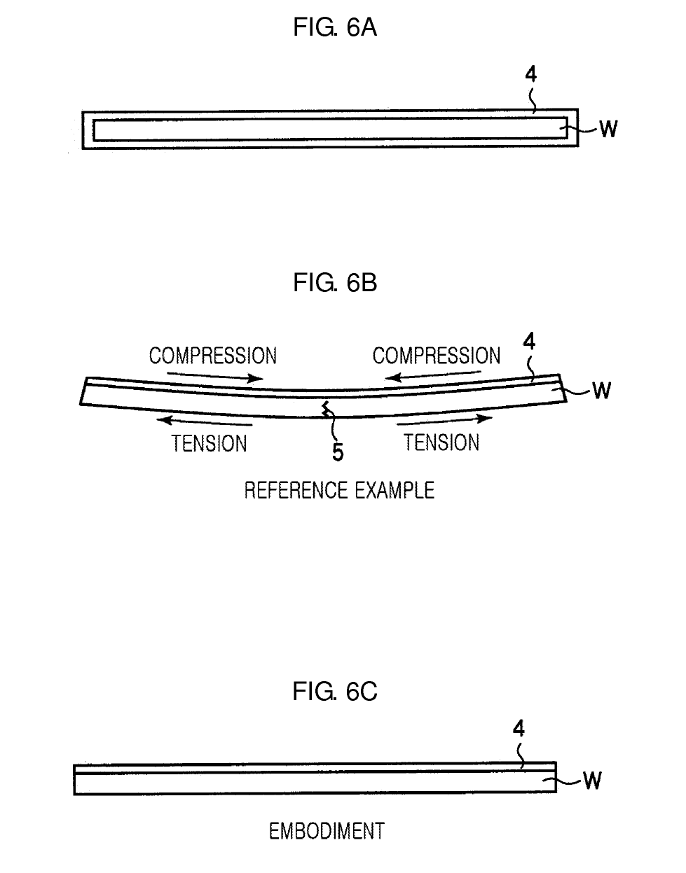

However, as shown in FIG. 6A, when the deposited structure body 4 is formed on the surface, the rear surface, and the side surface of the silicon wafer W, the silicon wafer W is not bended even if the silicon wafer W is exposed to room temperature. This is because the deposited structure body 4 is formed on each of the surface and the rear surface of the silicon wafer W, and stresses applied to the silicon wafer W from the deposited structure body 4 are balanced on the surface and the rear surface of the silicon wafer W.

However, when the deposited structure body 4 is removed from the rear surface and the side surface of the silicon wafer W through the rear surface etching and the bevel etching, the silicon wafer W starts to bend as shown in FIG. 6B. A bending amount of the silicon wafer W increases as the number of deposited structures (3-1 to 3-N) included in the deposited structure body 4 increases, because the stress applied to the silicon wafer W is increased. If a strength of the silicon wafer W exceeds a limitation, a crack 5 may occur in the silicon wafer W as shown in FIG. 6B and then the silicon wafer W is broken.

Thus, according to the method of depositing the silicon oxide film and the silicon nitride film of the present embodiment, the stress applied to the silicon wafer W from the silicon nitride films (2-1 to 2-N) included in the deposited structure body 4 may be reduced as described above. Therefore, even when the number of deposited silicon oxide films and the silicon nitride films in the deposited structure body 4 is increased, an increase in the bending amount of the silicon wafer W may be restrained as shown in FIG. 6C.

The method of depositing the silicon oxide films and the silicon nitride films according to embodiments of the present invention may be effectively applied to, for example, a method of manufacturing a semiconductor integrated circuit apparatus, in which devices such as transistors or memory cells are piled on the surface of the silicon wafer W in an upward direction, that is, the devices are so-called three-dimensionalized.

As described above, according to embodiments of the present invention, a method of depositing silicon oxide films and silicon nitride films, which is capable of restraining an increase in the bending amount of a substrate on which the deposited structure of the silicon oxide films and the silicon nitride films is formed even when the number of deposited silicon oxide films and the silicon nitride films is increased, and a film forming apparatus capable of executing the depositing method are provided.

While this invention has been particularly shown and described with reference to exemplary embodiments thereof, it will be understood by those skilled in the art that various changes in form and details may be made therein without departing from the spirit and scope of the invention as defined by the appended claims.

For example, in the above embodiment of the present invention, the deposited structures (3-1 to 3-N) include the silicon oxide films (1-1 to 1-N) on a lower portion and the silicon nitride films (2-1 to 2-N) on an upper portion; however, the silicon oxide films (1-1 to 1-N) may be formed on the upper portion and the silicon nitride films (2-1 to 2-N) may be formed on the lower portion.

In addition, the substrate is not limited to the semiconductor wafer, for example, the silicon wafer, and the present invention may be applied to other substrates such as a LCD glass substrate.

Otherwise, the present invention may be modified in various ways within the scope of the invention.

According to the present invention, a method of depositing the silicon oxide films and the silicon nitride films, which is capable of restraining an increase in the bending amount of the substrate on which the deposited structure of the silicon oxide films and the silicon nitride films is formed even when the number of deposited silicon oxide films and the silicon nitride films is increased, a film forming apparatus capable of executing the depositing method, and a method of manufacturing the semiconductor device by using the depositing method are provided.

What is claimed is:

1. A method of depositing a silicon oxide film and a silicon nitride film, the method comprising depositing the silicon oxide film and the silicon nitride film on a substrate,
wherein boron is added in a gas for forming the silicon nitride film.

2. A method of depositing a silicon oxide film and a silicon nitride film on a substrate, the method comprising:
accommodating a plurality of substrates, on each of which a deposited film of the silicon oxide film and the silicon nitride film is to be formed, in a processing chamber wherein a side portion of each of the substrates is held;
supplying a silicon oxide material gas and an oxidizing agent into the processing chamber, when the silicon oxide film is formed;
supplying a silicon material gas, a nitrating agent, and a boron-containing gas into the processing chamber, when the silicon nitride film is formed; and
forming the deposited films of the silicon oxide films and the silicon nitride films on a surface and a rear surface of each of the plurality of substrates by repeating the supplying of the silicon oxide material gas and the oxidizing agent and the supplying of the silicon material gas, the nitrating agent, and the boron-containing gas.

3. The method of claim 2, wherein a difference between a film forming temperature when the silicon oxide film is formed and a film forming temperature when the silicon nitride film is formed is within a range of 50° C. to 150° C.

4. The method of claim 2, wherein a film forming temperature when the silicon oxide film is formed and a film forming temperature when the silicon nitride film is formed are equal to each other.

5. The method of claim 2, wherein the boron-containing gas is boron trichloride.

6. The method of claim 2, wherein the silicon material gas is dichlorosilane and the nitrating agent is ammonia.

7. The method of claim 1, wherein the silicon nitride film is a film formed of SiₐB_{b}N_{c}, and an atomic composition ratio of the SiₐB_{b}N_{c} is controlled within ranges of a=25 to 17 atm %, b=22 to 32 atm %, and c=53 to 51 atm %.

8. The method of claim 7, wherein the substrate is a silicon wafer, and a stress applied to the silicon wafer from the film formed of the SiₐB_{b}N_{c} is controlled within a range of 100 to 600 MPa.

9. The method of claim 1, wherein the silicon nitride film is a SiBN film, in which the number of silicon atoms is less than the number of boron atoms.

10. The method of claim 9, wherein the silicon nitride film is a film formed of SiₐB_{b}N_{c}, and an atomic composition ratio of the SiₐB_{b}N_{c} is controlled within ranges of a=20 to 17 atm %, b=28 to 32 atm %, and c=52 to 51 atm %.

11. The method of claim 10, wherein the substrate is a silicon wafer, and a stress applied to the silicon wafer from the film formed of the SiₐB_{b}N_{c} is controlled within a range of 100 to 300 MPa.

12. The method of claim 1, wherein the silicon nitride film is a SiBN film, in which the number of silicon atoms is equal to or greater than the number of boron atoms.

13. The method of claim 12, wherein the silicon nitride film is a film formed of SiₐB_{b}N_{c}, and an atomic composition ratio of the SiₐB_{b}N_{c} is controlled within ranges of a=25 to 24 atm %, b=22 to 24 atm %, and c=53 to 52 atm %.

14. The method of claim 13, wherein the substrate is a silicon wafer, and a haze level of the film formed of the SiₐB_{b}N_{c} is controlled within a range of 0.005 ppm to 0.01 ppm.

15. A film forming apparatus forming a deposited film of a silicon oxide film and a silicon nitride film on a substrate, the film forming apparatus comprising:
a processing chamber which accommodates a plurality of substrates, on which the deposited film of the silicon oxide film and the silicon nitride film is to be formed, wherein a side portion of each of the substrates is held;
a gas supply mechanism which supplies a gas used in a process into the processing chamber;
an exhauster which evacuates an inside of the processing chamber; and
a controller which controls the gas supply mechanism and the exhauster,
wherein the controller controls the gas supply mechanism and the exhauster to execute the supplying of the silicon oxide material gas and the oxidizing agent, the supplying of the silicon material gas, the nitrating agent, and the boron-containing gas, and the forming of the deposited films of the silicon oxide films and the silicon nitride films, of claim 2.

16. A method of manufacturing a semiconductor device including a deposited film, in which a silicon oxide film and a silicon nitride film are repeatedly deposited, the method comprising:
accommodating a plurality of substrates, on each of which the deposited film of the silicon oxide film and the silicon nitride film is to be formed, in a processing chamber wherein a side portion of each of the substrates is held;
supplying a silicon oxide material gas and an oxidizing agent into the processing chamber, when the silicon oxide film is formed;
supplying a silicon material gas, a nitrating agent, and a boron-containing gas into the processing chamber, when the silicon nitride film is formed;
forming the deposited films of the silicon oxide films and the silicon nitride films on a surface and a rear surface of each of the plurality of substrates by repeating the supplying of the silicon oxide material gas and the oxidizing agent and the supplying of the silicon material gas, the nitrating agent, and the boron-containing gas; and
removing the deposited film formed on the rear surface of each of the plurality of substrates, after finishing the forming of the deposited film.

17. The method of claim 16, wherein a difference between a film forming temperature when the silicon oxide film is formed and a film forming temperature when the silicon nitride film is formed is within a range of 50° C. to 150° C.

18. The method of claim 16, wherein a film forming temperature when the silicon oxide film is formed and a film forming temperature when the silicon nitride film is formed are equal to each other.
